(19) United States
(12) Patent Application Publication
(10) Pub. No.: US 2013/0271923 A1
(43) Pub. Date: Oct. 17, 2013

(54) ELECTRICAL APPARATUS

(71) Applicant: Christopher John Smethurst, Leeds (GB)

(72) Inventor: Christopher John Smethurst, Leeds (GB)

(73) Assignee: Harvard Engineering PLC

(21) Appl. No.: 13/446,877

(22) Filed: Apr. 13, 2012

(51) Int. Cl. H05K 7/02

(52) U.S. Cl. 361/728

(57) ABSTRACT

Electrical apparatus comprises: a housing; an electrical circuit in the housing comprising a circuit component; a metallic component in the housing, for dissipating heat generated in the circuit component; and a thermally conductive body arranged between a surface of the circuit component and a surface of the metallic component. The housing comprises a first housing portion and a second housing portion, the second housing portion being adapted to locate on the first housing portion in a closed position in which the electrical circuit, metallic component, and body are enclosed within the housing, the second housing portion being adapted such that, when in the closed position, the second housing portion urges the surface of the circuit component towards the surface of the metallic component such that the body is in contact with both of these surfaces to assist transfer of heat generated in the circuit component to the metallic component.

### FIELD OF THE INVENTION

The present invention generally relates to electrical apparatus comprising a housing and at least one electrical component (which may be a circuit component of an electrical circuit located inside the housing) in which heat is generated during electrical operation of the electrical component. In particular, although not exclusively, certain embodiments of the invention relate to ballasts for high intensity discharge (HID) lamps. Certain embodiments are concerned with the problem of the removal or dissipation of heat from one or more electrical components enclosed within the housing of electrical apparatus.

### BACKGROUND

A wide variety of pieces of electrical apparatus comprising electrical circuits enclosed in housings are known, with those electrical circuits comprising one or more electrical components (which can also be described as circuit components) in which substantial amounts of heat are generated during operation of the circuit. A general problem of such pieces of apparatus is the removal of that heat generated in the electrical components (e.g. devices). It should be appreciated that throughout this specification the term “electrical” is being used in the broad sense of meaning operated, at least in part, by electricity, and includes/encompasses “electronic”, i.e. concerned with, using, or operated by devices in which electrons are conducted through a semiconductor, free space, or a gas. Thus, in this specification, the term “electrical circuit” includes electronic circuits, and circuits comprising electronic and non-electronic components.

One such known piece of electrical apparatus is a ballast for HID lamps. HID lamps are a type of electrical lamp which produces light by means of an electric arc between electrodes housed inside a tube filled with suitable material, such as a gas and/or metal salts. An arc between the electrodes first has to be struck, and once started, the arc forms a plasma within the tube. A ballast (which may also be described as an electronic lamp ballast) is a known piece of electrical apparatus for striking a lamp such as an HID lamp, and then controls current flowing in the lamp. Such ballasts typically comprise at least one relatively large inductor used in a resonant circuit for producing a high voltage to strike the arc, and at least one relatively large inductor for controlling (limiting) the amount of current flowing in the lamp after the arc has been struck. Typically, significant amounts of heat are generated in these inductors during striking and/or subsequent operation, and in general it is desirable to remove this heat from the circuit, not least because temperature rises of the inductors also increases their resistances, and hence leads to further dissipation of energy as heat during operation of the circuit.

In addition to heat being generated in inductors, substantial amounts of heat may also be generated in other circuit elements, devices, and components, such as windings, transformers, switching devices, processors, integrated circuits etc.

To assist in the removal of heat from circuit components it may be desirable to incorporate a heat dissipating component within the housing of the electrical apparatus, that heat dissipating component being a metal/metallic component or a component being made of some other thermally conductive material. However, such a heat dissipating component, or heat sink component, is an extra component for the apparatus, increasing the complexity and cost of the apparatus overall. Furthermore, even if heat can be transferred from the heat dissipating circuit component into the heat dissipating component, then there remains the problem of how to get that heat out of the housing. Certain known pieces of electrical apparatus incorporate fans for the removal of heat, but clearly this represents an increase in complexity and cost of the apparatus.

In certain known electrical apparatus, it is desirable for the apparatus to incorporate an electrically conductive metal/metallic housing for EMC screening purposes. EMC (electromagnetic compatibility) is concerned with the unintentional generation, propagation and reception of electromagnetic energy with reference to the unwanted effects (i.e. electromagnetic interference) that such energy may induce. Thus, certain pieces of electrical apparatus include metal housings for EMC screening purposes, to screen the electrical circuit housed inside the apparatus from electromagnetic interference. In such pieces of apparatus, a heat dissipating circuit component could be attached to the metallic housing in order for the housing to dissipate the generated heat, but a problem is that the metal housing is electrically conductive as well as thermally conductive. This can clearly have adverse safety implications. Also, if the heat dissipating circuit component is attached to the metal housing by fastening means such as a screw or nut and bolt, then this fastening means may spoil the integrity of the housing, look unsightly, or cause further safety issues with regard to electrical isolation. If a heat generating circuit component were to be bonded to the metallic housing, to avoid use of fastening screws etc., then a further problem is caused by differential thermal expansion/contraction of the metallic housing and bonding material and circuit component itself. This can cause cracking of the bonding material, which would at least reduce its effectiveness in conducting heat from the circuit component to the metal housing, and the bonding may fail altogether, resulting in the electrical circuit component becoming detached from the housing.

In apparatus where a metal housing is desirable, it may also be desirable or necessary to incorporate an electrically insulating outer housing (formed from plastic, for example) surrounding the inner metal housing for safety purposes (i.e. primarily for electrical isolation, such that a user cannot touch the inner metal housing). A problem with such arrangements is, however, that the presence of the outer plastic housing can impede heat dissipation from the metal housing. Thus, even if a heat dissipating circuit component were arranged to transfer generated heat into the metal housing, the electrically insulating outer housing could inhibit dissipation of that heat from the metal housing into the surrounding environment. In order to try to improve this transfer of heat out of the apparatus, the plastic outer housing could be bonded to the metal inner housing. However, problems are again encountered as a result of differential thermal expansions/contractions. Such differences can lead to the cracking or complete failure of bonding between the metal housing and outer plastic housing, and/or can lead to bending or other distortion of the bonded structure.

It is possible to leave a gap between a metallic inner housing and a plastic outer housing, but such a gap inhibits flow of heat out of the apparatus into the surrounding environment.

In electrical apparatus where a heat sinking component is employed, the fastening of the heat generating circuit component to the heat sink component is problematic. Use of fastening means such as screws, bolts, clips, etc. increases the complexity and cost of the apparatus overall, and such fastening means may become loose over time. Bonding of the heat generating component to the heat sink component is also problematic, in view of differential thermal expansions/contractions.

### SUMMARY OF THE INVENTION

It is an aim of certain embodiments of the invention to solve, mitigate, or obviate, at least partly, at least one of the problems and/or disadvantages associated with the prior art. Certain embodiments aim to provide at least one of the advantages described below.

According to a first aspect of the present invention there is provided electrical apparatus: comprising:

a housing (which may also be described as a housing assembly);

an electrical circuit located inside the housing and comprising a circuit component in which heat is generated during operation of the circuit;

a metallic component located inside the housing, for dissipating heat generated in the circuit component; and

a thermally conductive body arranged between a surface of the circuit component and a surface of the metallic component,

wherein the housing comprises a first housing portion and a second housing portion, the second housing portion being adapted to locate on the first housing portion in a closed position in which the electrical circuit, metallic component, and body are enclosed within the housing,

the second housing portion being adapted such that, when in said closed position, the second housing portion urges said surface of the circuit component towards said surface of the metallic component such that the body is in contact with both of said surfaces to assist transfer of heat generated in the circuit component to the metallic component.

It will be appreciated that the metallic component may, in certain embodiments, be a metal component. Also, in an alternative aspect, the metallic component may be replaced by a thermally conductive component located inside the housing, for dissipating heat generated in the circuit component. This thermally conductive component may additionally be electrically conductive. Thus the metallic component may be formed from a metal, from a non-metal having the metallic properties of relatively high thermal and electrical conductivities, or may be replaced by a non-metallic thermally conductive component in alternative embodiments and aspects of the invention.

It will be appreciated that the use of the metallic or metal component, or equivalently the use of a heat-dissipating component which is both thermally and electrically conductive, provides the advantage that heat dissipation is facilitated, and at the same time a degree of screening from electromagnetic radiation is provided.

It will be appreciated that the arrangement of the electrical apparatus in accordance with this first aspect of the invention provides the advantage that good thermal transfer of heat from the circuit component to the metallic component is achieved without the need for fastening means to fasten the circuit component to the metallic component, and without the circuit component being bonded to the metallic component. The use of the thermally conductive body arranged between the metal component and the heat-generating component is that the arrangement is tolerant of variations in positioning and/or size of the heat-generating component. Thus, the size (including thickness) of the thermally conductive body may be selected to suit the gap between a particular circuit component and the metallic component. Advantageously, the thermally conductive body may be a body of solid material which softens as temperature increases. Thus, the second housing portion urges the heat-generating component towards the metallic component, squeezing the thermally conductive body between the two, and the thermally conductive body can deform under that urging force, thereby maintaining good thermal contact between the surfaces contacting it on either side. Thus, in certain embodiments the thermally conductive body may be a thermal pad, which may be a square or rectangle (or indeed any other shape) of solid material, such as paraffin-based material. Such thermal pads can thus fill the gap between the heat-generating component and the heat-sinking metallic component. Even though the surface of the heat-generating component and the surface of the metallic component may not be perfectly flat or smooth, the thermal pad can still provide good thermal contact between these two surfaces.

The use of the second housing portion to urge the surface of the circuit component into thermal contact with the thermally conductive body avoids the use of additional fastening means, and exploits the fact that the second housing portion already has to be located in the closed position with respect to the first housing portion in order to enclose the electrical circuit inside.

In certain embodiments, the thermally conductive body is electrically insulating, so as to provide electrical isolation between the metallic component and the circuit component.

In certain embodiments, the circuit component is one of: an inductor; a winding; a transformer; a capacitor; a switching device; and a processor.

In certain embodiments, the apparatus is a ballast (e.g. an electronic ballast) for an HID lamp.

In certain embodiments, the first housing portion comprises a first plastic body, and the second housing portion comprises a second plastic body.

In certain embodiments, the second housing portion is adapted to urge, via the circuit component, a second surface of the metallic component against a surface (e.g. an inner surface of a side wall) of the first housing portion when in the closed position. Thus, as the second housing portion is located on the first housing portion in the closed position, it both urges the surface of the circuit component against the thermally conductive body to achieve good thermal contact, and also urges the metallic component against the surface of the first housing portion to achieve good thermal contact between the metallic component and the first housing portion. Advantageously, this improves the conduction of heat from the heat-generating component, through the thermally conductive body (e.g. thermal pad), to the metallic component, and then to the first housing portion, from where it can be dissipated into the surrounding environment. This improved thermal conduction and dissipation of generated heat is achieved without bonding the surface of the metallic component to the first housing portion, thereby avoiding problems with differential thermal expansions/contractions.

In certain embodiments, the second housing portion comprises an urging member arranged to extend into a volume enclosed by the housing when the second housing portion is in the closed position, the urging member being adapted to urge said surface of the circuit component towards said surface of the metallic component.

In certain embodiments, the urging member is rigid, and in embodiments where the second housing portion comprises a plastic body, the urging member may be an integral part of the plastic body (formed, for example, by moulding).

In certain embodiments, the urging member comprises an urging surface shaped so as to progressively urge said surface of the circuit component towards said surface of the metallic component as the second housing portion is moved into the closed position.

In certain embodiments, the urging surface may be arranged to directly engage a surface of the heat-generating component in order to urge it towards the metallic component. However, in alternative embodiments, the circuit component is mounted on a first side of a board, and the urging member is arranged to press on a second, opposite side of the board to urge said surface of the circuit component towards said surface of the metallic component when the second housing portion is in the closed position. In such embodiments, the urging member may comprise an urging surface shaped so as to engage the second surface of the board and progressively urge said surface of the circuit component towards said surface of the metallic component as the second housing portion is moved into the closed position.

In certain embodiments, the urging surface comprises a curved ramp portion and a linear ramp portion, for example with the curved ramp portion being arranged to engage the surface of the board first as the second housing portion is brought towards the closed position. Then, as the second housing portion (which in certain embodiments may be described as a lid) is brought closer to the closed position, the contact point between the board and the urging surface moves from the curved ramp portion to the linear ramp portion. This linear ramp portion may be arranged to have a small gradient such that as the lid is moved in one direction towards the closed position this can result in a much smaller deflection of the board carrying the heat dissipating component in a perpendicular direction, towards the metallic component.

In certain embodiments, the board is coupled to a main circuit board of the electric circuit, and this coupling may be arranged in a manner such that the board can move or slide in at least one direction relative to the main circuit board.

In certain embodiments, the metallic component is attached to the first housing portion. In certain preferred embodiments, the metallic component is attached to the first housing portion at a single attachment point so as to permit relative movement between surfaces of the metallic element and first housing potion in response to differential thermal expansions and contractions.

In certain embodiments, the metallic component comprises at least part of a metallic inner housing, for example a metal housing arranged to provide EMC screening.

In certain embodiments, the circuit component is a first circuit component, the thermally conductive body is a first thermally conductive body, and the metallic component is a first metallic component, the electrical circuit comprises a second circuit component in which heat is generated during operation of the circuit, the apparatus comprises a second metallic component located inside the housing, for dissipating heat generated in the second circuit component, and a second thermally conductive body arranged between a surface of the second circuit component and a surface of the second metallic component, the second housing portion being further adapted such that, when in said closed position, the second housing portion urges said surface of the first circuit component towards said surface of the first metallic component such that the first thermally conductive body is in contact with both of said surfaces to assist transfer of heat generated in the first circuit component to the first metallic component, and urges said surface of the second circuit component towards said surface of the second metallic component such that the second thermally conductive body is in contact with both of said surfaces to assist transfer of heat generated in the second circuit component to the second metallic component.

In certain embodiments, the first and second metallic components are first and second portions respectively of a metallic inner housing.

In such embodiments, each of the first and second portions of a metallic inner housing may be attached to the first housing portion.

In such embodiments, the first and second portions of the metallic inner housing are attached to the first housing portion such that a thermal expansion gap is arranged between the first and second metallic inner housing portions.

In certain embodiments, the second housing portion is adapted to urge, via the first and second circuit components, respective surfaces of the first and second metallic components against respective inner surfaces of opposite walls of the first housing portion.

Advantageously, the location of the second housing component (e.g. lid) in the closed position urges the first and second components in opposite directions, to push them against thermal pads to achieve good thermal contact to first and second metallic components respectively, and at the same time to urge surfaces of those metallic components against opposite walls of the outer, plastic housing. In such embodiments, the urging forces in these opposite directions may therefore be balances, avoiding problems of potential distortion of the housing when assembled.

Advantageously, the second housing portion may be adapted to support the opposite walls when in the closed position (i.e. support those walls against the urging forces which are pressing the metal components generally outwards, against the outer housing side walls, which would otherwise tend to push those side walls outwards).

In certain embodiments, the apparatus comprises an urging member arranged to urge the first circuit component surface into thermal contact with the first thermally conductive body and urge the second circuit component surface into thermal contact with the second thermally conductive body at the same time.

In certain embodiments, the apparatus further comprises a first urging member arranged to urge at least the first circuit component into contact with the first thermally conductive body, and a second urging member arranged to urge at least the second circuit component into contact with the second thermally conductive member.

In certain embodiments, the second housing portion further comprises a third portion of the metallic inner housing. Thus, this third portion of metal inner housing can provide even more complete EMC screening of the electrical circuit contained within the housing. In certain embodiments, the apparatus also comprises electrical connecting means for electrically connecting the third portion of metallic inner housing to the first and second portions of metallic inner housing when the lid is in the closed position. These connecting means or elements can take a variety of forms, such as one or more springs or sprung members.

In certain embodiments, the apparatus further comprises a snap-fit mechanism adapted to secure the second housing portion in the closed position. Advantageously, as the lid in certain embodiments is placed into the closed position, it exerts an urging force on one or more of the heat-dissipating components inside, to bring them into good thermal contact with the relevant thermal pads. In general, this application of urging forces will result in a force resisting closure of the lid. However, the snap-fit mechanism is able to retain the lid in the closed position, against that resisting force. Thus, the lid is maintained in the closed position, and the urging forces are continued to be applied to achieve good thermal contacts.

According to another aspect of the invention, there is provided electrical apparatus comprising:

a housing (which may also be described as a housing assembly);

an electrical circuit located inside the housing and comprising a circuit component in which heat is generated during operation of the circuit; and

a metallic component located inside the housing, for dissipating heat generated in the circuit component,

wherein the housing comprises a first housing portion and a second housing portion, the second housing portion being adapted to locate on the first housing portion in a closed position in which the electrical circuit and metallic component are enclosed within the housing,

the second housing portion being adapted such that, when in said closed position, the second housing portion urges a surface of the circuit component against a surface of the metallic component to assist transfer of heat generated in the circuit component to the metallic component.

Thus, in this other aspect of the invention, a thermally conductive body between the circuit component and metallic component may not be necessary. A surface of the circuit component can be urged into direct contact with the surface of the metallic component, to achieve good thermal transfer without the need for attachment means or bonding between the two surfaces. This does, however, require the mating surfaces to be substantially flat in certain embodiments. In certain embodiments of this aspect, a heat transfer medium may also be used between the surfaces of the circuit component and metallic component. For example, a thermal grease or other thermally conductive, yet electrically insulative, material may be provided between the two surfaces to improve heat transfer.

It would be appreciated that the various features of the first aspect of the invention may be employed in this second aspect of the invention, with corresponding advantage.

According to another aspect of the invention, there is provided electrical apparatus comprising:

a housing (which may also be described as a housing assembly);

an electrical component located inside the housing and in which heat is generated during electrical operation of the electrical component; and

a metallic component located inside the housing, for dissipating heat generated in the electrical component,

wherein the housing comprises a first housing portion and a second housing portion, the second housing portion being adapted to locate on the first housing portion in a closed position in which the electrical component and metallic component are enclosed within the housing,

the second housing portion being adapted such that, when in said closed position, the second housing portion urges a surface of the electrical component against a surface of the metallic component to assist transfer of heat generated in the electrical component to the metallic component.

Again, it will be appreciated that features of the first and second aspects of the invention described above may be employed in this third aspect, with corresponding advantage.

According to a fourth aspect of the invention, there is provided electrical apparatus comprising:

a housing (which may also be described as a housing assembly);

an electrical component located inside the housing and in which heat is generated during electrical operation of the electrical component;

a metallic component located inside the housing, for dissipating heat generated in the electrical component; and

a thermally conductive body arranged between a surface of the electrical component and a surface of the metallic component,

wherein the housing comprises a first housing portion and a second housing portion, the second housing portion being adapted to locate on the first housing portion in a closed position in which the electrical component, metallic component, and body are enclosed within the housing,

the second housing portion being adapted such that, when in said closed position, the second housing portion urges said surface of the electrical component towards said surface of the metallic component such that the body is in contact with both of said surfaces to assist transfer of heat generated in the electrical component to the metallic component.

Again, it will be appreciated that features of the first, second, and third aspects of the invention may be employed in embodiments of this fourth aspect of the invention, with corresponding advantage.

The foregoing and other objects, features, and advantages of the invention will become more apparent from the following detailed description, which proceeds with reference to the accompanying figures.

### BRIEF DESCRIPTION OF THE DRAWINGS

Embodiments of the invention will now be described with reference to the accompanying drawings, in which:

FIG. 1 is a perspective view from above of part of electrical apparatus embodying the invention, with the upper housing portion or lid removed;

FIG. 2 is another perspective view of the first embodiment, from a vertical cross section taken through the apparatus;

FIG. 3 is another perspective view of the first embodiment, taken from a cross section at a different position with respect to the nominal Y axis of the apparatus;

FIG. 4 is another cross sectional view of part of the first embodiment;

FIG. 5 is a view from above of some of the components of the first embodiment;

FIG. 6 is a schematic cross section of another embodiment of the invention; and

FIG. 7 is a schematic cross section of yet another embodiment of the invention.

### DETAILED DESCRIPTION

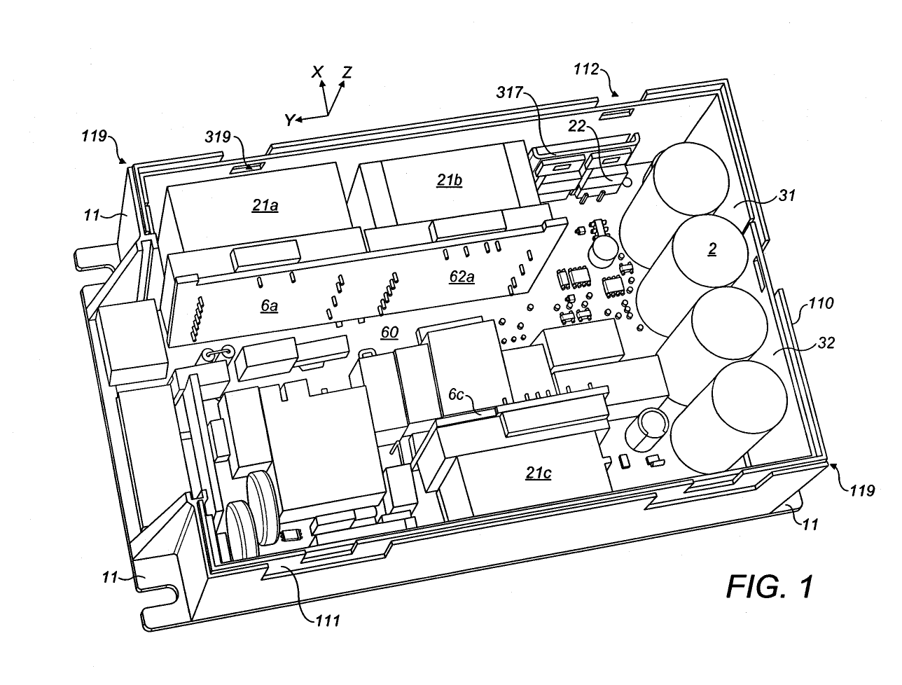

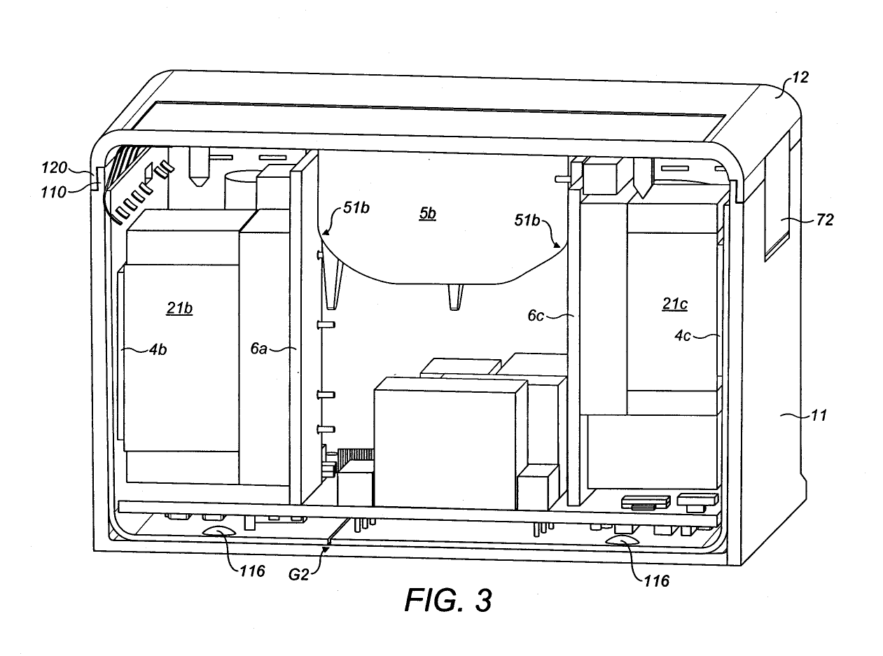

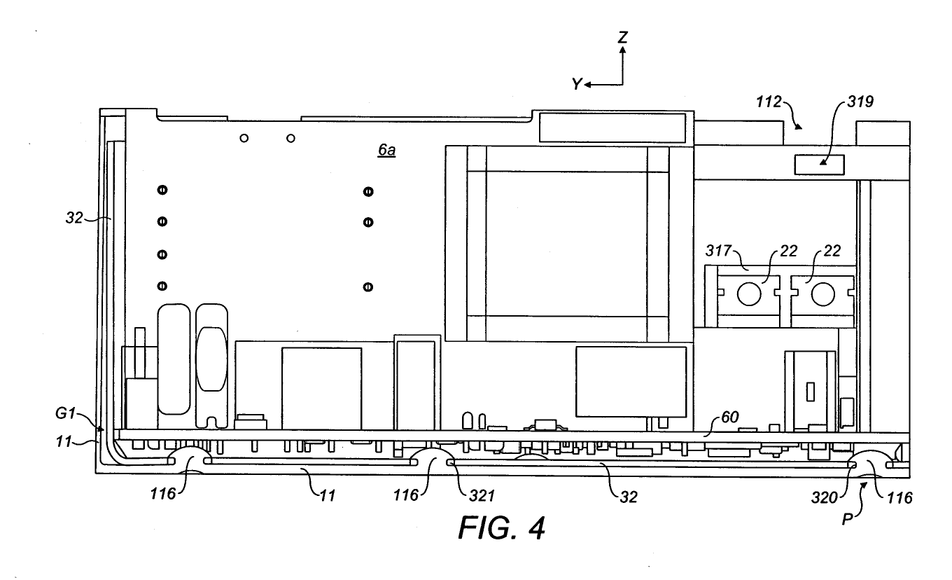

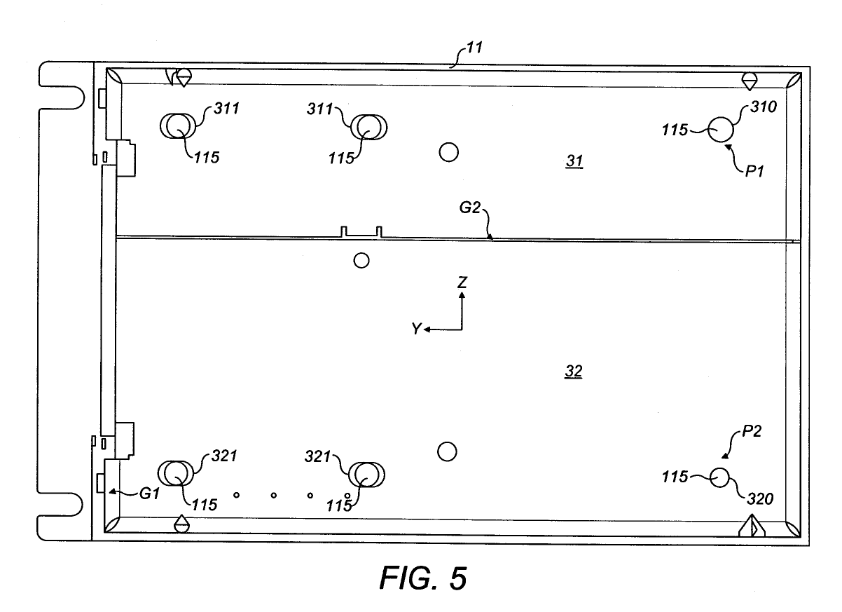

Referring now to FIGS. 1-5, in one embodiment of the invention the electrical apparatus is an electronic ballast for an HID lamp, comprising a housing 1 enclosing an electrical circuit 2 (in this example an electronic ballast circuit) and a plurality of metal components 31a, 31b, 31c, which together form a metallic inner housing providing EMI screening around the circuit. In this example the housing 1 is a housing assembly, comprising a first housing portion 11, which may also be described as a housing base portion, and a second housing portion 12, which in this example may be described as a lid or cover portion. The base portion 11 comprises a moulded plastic body having a raised lip 110 and shoulder 119 provided at an upper edge for locating and seating the lid portion 12 in a closed position. The base portion 11 is also formed with a plurality of recesses 111 and cut outs 112, the recesses 111 providing a seating for corresponding arms 72 of the lid, and the cut outs 112 enabling catches provided on those arms 72 to engage with slots 319 provided in the metallic inner housing when the lid 12 is in the closed position. The circuit 2 comprises a plurality of circuit components in which substantial amounts of heat are generated during electrical operation of the circuit, namely windings 21a, 21b, and 21c. Windings 21a and 21b are mounted on a first circuit board 6a which itself extends generally perpendicularly up from a main circuit board 60. Similarly, winding 21c is mounted on a second circuit board 6c, which is also mounted on the main circuit board 60. The coupling between the circuit boards 6a, 6c and the main circuit board 60 is such that each of the boards 6a and 6c is able to slide by a limited amount in the X direction indicated in the figures in response to urging forces applied in that direction. As will be appreciated, the boards 6a and 6c may be engaged in suitably shaped slots in the main circuit board 60. In alternative embodiments, the boards 6a and 6c may be relatively securely fixed to the main circuit board 60, with movement in the X direction being permitted by flexibility of the boards 6a and 6c themselves.

In this example, a surface 210a of the first winding faces an inner surface 310 of the first metal housing portion 31. A corresponding surface of the second winding faces the surface 310 of metal component 31, and a corresponding surface of the third winding faces a corresponding surface of the second portion of the metal inner housing 32. Flexible thermal pads are arranged in between these facing surfaces. Thus, a first thermal pad 4a is arranged between surface 210a and 310, a second thermal pad is arranged between winding 21b and surface 310 (that pad is not visible in the views shown in the drawings), and a third pad 4c is arranged between the third winding 21c and wall of component 32. The pads have suitable thicknesses to substantially fill the relevant gaps, even when the lid is removed. Typical thicknesses range from 0.5 mm to 1, 2, 3, 4, or 5 mm. Other thicknesses may be employed in alternative embodiments.

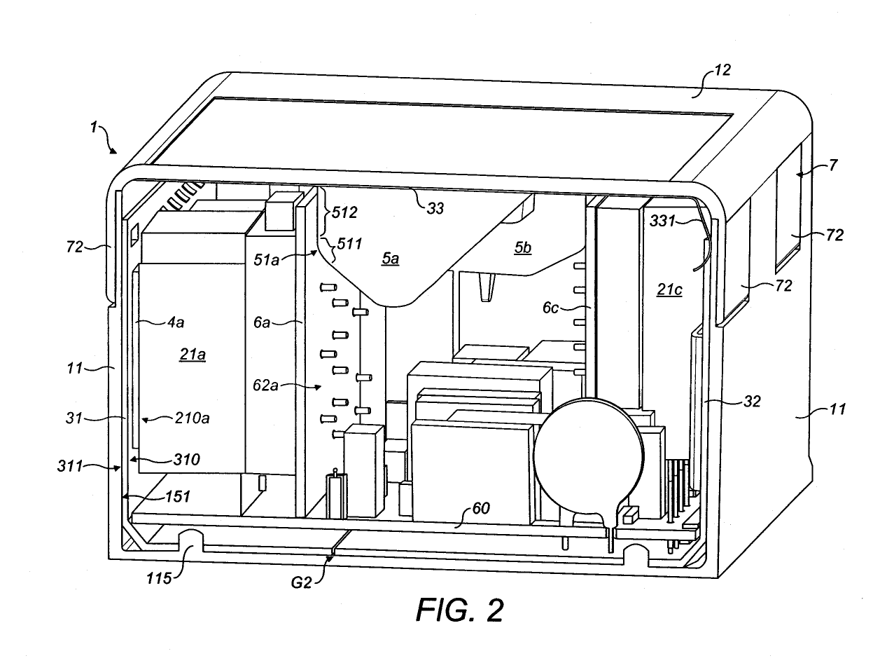

When the lid 12 is in the closed position as shown in FIG. 2 it is secured in place by the snap-fit mechanism 7. The lid 12 is adapted such that, in this closed position, it urges the first winding 21a in the positive X direction of the figures, so as to squeeze the pad 4a between the surfaces 210a and 310, and at the same time urges an outer surface 311 of the metal component 31 against the inner surface 151 of the side wall of the housing base portion 11. At the same time, the lid 12 urges the second and third windings 21b and 21c against their respective pads and portions of their metal inner side walls, and also urges those metal side walls outwardly with respect to the plastic housing body. This achieves good thermal conduction from the circuit components 21a, 21b, and 21c to the metal components 31 and 32, and also achieves good thermal conduction from the metal components 31, 32 to the outer housing base 11. This thermal conduction is achieved without bonding between any of the engaging/abutting surfaces. In this first embodiment, this urging action provided by the lid 12 is achieved by means of first and second urging members 5a, 5b. Each of these urging members in this example is substantially rigid and an integral part of the moulded plastic body of the lid portion 12. Each urging member extends from the inner surface of the lid 12 down into the volume enclosed within the housing, and is relatively elongate in the X direction, and relatively narrow in the Y direction. Thus, in this example each urging member can also be described as a fin, wedge, rib, or protrusion. The first urging member 5a is adapted to urge the first circuit component 21a against thermal pad 4a. Urging member 5a achieves this by means of an urging surface 51a which is adapted to engage a surface 62a of mounting board 6a when the lid 12 is moved towards the closed position (in a direction generally corresponding to the negative Z direction in the figures). As the lid is brought into the seated, closed position, the urging surface 51a progressively pushes the mounting board 6a in the positive X direction in FIG. 2, so as to compress the thermally conductive body 4a between the surfaces 210a and 310 of the component 21a and metallic housing portion 31. This urging surface 51a in this example comprises a curved ramp portion 511 which is the first portion to engage the broad surface 62a when the lid is brought towards the closed position. The contact point between the urging surface 51a and broad surface 62a then moves as the lid is brought further towards the closed position, ending on the linear ramp portion 512. The slope of this linear ramp portion 512 (i.e. its inclination with respect to the Z axis) is such that a unit of movement of the lid 12 in the negative Z direction results in a much smaller movement of the device 21a in the positive X direction. Thus, the slope of the linear portion provides a mechanical advantage and the urging member 5a can apply a substantial urging force to compress the thermal pad (and so achieve good thermal conduction) for a relatively small force required to close the lid 12 (and retain it in place, by means of the snap-fit mechanism. With the pad 4a compressed between the component 21a and metal component 31, heat generated in the component 21a is readily transferred into the metal component 31 by conduction, and thereafter into the outer plastic housing wall, from which it can dissipate into the surrounding environment. The elongate shape of the urging member 5a in this first embodiment in the X direction provides the urging member with substantial rigidity, and enables it to apply a substantial urging force to compress the thermal pad 4a without the urging member being required to be formed from a substantial volume of material.

In this first embodiment, the lid portion 12 comprises the second urging member 5b, which functions generally in the same manner as the first urging member 5a. However, this second urging member 5b is adapted to engage surfaces of both the first mounting board 6a and second mounting board 6c as the lid 12 is brought into the closed position, so as to urge the second and third electrical components 21b and 21c apart simultaneously, so as to compress their respective thermal pads against the respective metal components 31, 32, and also urge those metal components 31, 32 against the opposite side walls of the plastic outer housing base 11. Again, the second urging member is elongate in the X direction, relatively thin in the Y direction, and extends downwards from the lid 12 when the lid is in the closed position. Again, this general form provides the second urging member 5b with rigidity, and enables substantial urging forces to be applied to the second and third components 21b, 21c at the same time.

It will be appreciated, that in this first embodiment, the urging forces applied by the urging members tend to push the inner metal housing components 31 and 32 generally outwards, and this would tend to distort the outer walls of the plastic housing base 11. However, the lid portion 12 in this example is adapted to support these walls when in the closed position, by means of a downwardly extending lip 120 adapted to fit over the lip 110 of the base portion and seat on the shoulder 119. The snap-fit mechanism 7 then secures the lid 12 in the closed position.

Looking at FIG. 2, the second housing portion 12 also comprises a metal component 33 which forms a third portion of the metal inner housing, and a plurality of conductive springs (which may also be described as sprung arms) which electrically connect the metal component 33 to the first and second metal components 31, 32 when the lid is in the closed position. Thus, when the lid is closed the first, second, and third metal housing components together provide EMI screening which surrounds the enclosed circuit.

In this first example, the first and second metal housing components 31 and 32 are each formed from bent sheet metal, and are located in the base portion 11 of the outer plastic housing by means of a plurality of moulded pegs 115 extending upwardly from the inner base wall of the housing portion 11. These pegs are received in corresponding apertures in the metal components 31 and 32. To enable differential thermal expansion of the metal components 31 and 32 in both the X and Y directions with respect to the moulded plastic base portion 11 the metal components 31 and 32 are located on the pegs 115 such that an expansion gap G2 exists between them, that gap extending generally in the Y direction. Furthermore, the first metal component 31 is located on three pegs 115 by means of a single, close fitting circular aperture 310 and a plurality of slots 311 fitting over the remaining pegs. During manufacture, the pegs are deformed to form generally mushroom shaped, or domed upper ends 116 which retain the metal components 31 and 32 on the pegs, preventing movement in the Z direction. However, the slots 311 and 321 enable thermal expansion of the components 31 and 32 with respect to their single fixed attachment positions P1 and P2 resulting from temperature changes. Thus, in this first example, each of the first and second metal housing components 31 and 32 is attached to the outer housing base portion 11 at a single respective attachment point. The other locating pegs or members 115 are a loose fit in the respective holes (slots 311 and 321) to permit thermal expansion. An expansion gap G1 is provided at the ends of the metal members 31, 32 remote from the attachment points P1, P2. The mounting of the metal components 31, 32 in the housing base portion 11 is such that surface of those metal components can slide with respect to housing wall surfaces under thermal expansion/contraction. The base portion of the metal inner housing is, in effect, split into two halves, with a small gap between. In addition to the windings being urged against their respective pads 4 for heat-sinking purposes, in this first example the circuit also comprises a pair of MOSFETS 22 which are attached to an inwardly protruding section 317 of the first metal housing portion 31. The inward protrusion enables a variety of attachment means to be employed, including, for example, screws, bolts, clips etc. Thus, heat generated in the windings 21a, 21b, 21c and in the MOSFETS 22 is conducted into the metal components 31 and 32, which dissipate that heat over a relative large area. Thus, heat can be dissipated from the outer surfaces of the housing base portion 11 without a large temperature difference existing across the housing walls. The larger the area over which the heat is dissipated, the smaller the temperature difference between the inner and outer wall surfaces of the plastic housing base 11 for a given rate of flow of heat out of the enclosure.

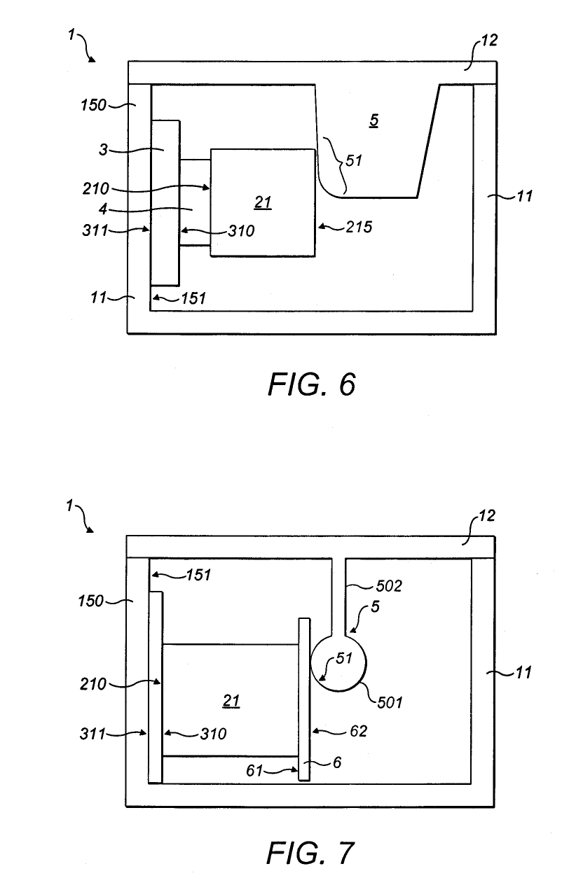

Referring now to FIG. 6, this is a schematic cross section of yet another embodiment of the invention. Again, the second housing portion 12 comprises an urging member 5 having an urging surface 51. In this example, rather than urging the electrical component 21 towards an outer wall of the first housing portion 11 by pushing on a mounting board, the urging surface 51 directly engages a surface 215 of the electrical component 21. The second housing portion 12 is shown in the closed position, in which the urging surface 51, by means of pressing on the surface 215, is squeezing the thermally conductive body 4 between surface 210 of the device 21 and surface 310 of a metallic element, and at the same time is urging a surface 311 of that metallic element 3 against a surface 151 of a wall 150 of the first housing portion 1.

Referring now to FIG. 7, this is a schematic cross section of an alternative embodiment. Here, the electrical component in which heat is generated during operation is mounted on a board 6, in particular mounted on a first side 61 of the board. The urging member 5 is arranged to engage an opposite surface 62 of the board 6 to press a surface 210 of the device 21 into direct contact with a surface 310 of a metal component 3. At the same time, an opposite surface 311 of the metal component 3 is urged against an inner side wall surface 151 of a side wall 150 of the base portion of the housing 11. Although not visible in the figure, in similar embodiments a thin layer of thermally conductive material, such as thermal grease, may be employed between the surfaces 210 and 310, and/or between surfaces 151 and 311 in order to improve thermal conduction of heat generated in the component 21 out of the apparatus. In this embodiment, the urging member comprises a substantially rigid head portion 501, with part of the external surface of that head portion providing the urging surface 51. The urging member also comprises a resilient portion 502, which in certain embodiments may take the form of a resilient arm or web, supporting the head portion. As the lid 12 is brought into the closed position, the resilient portion 502 is able to flex, keeping the urging surface in contact with the surface 62, and exerting an urging force as a result of that resilience.

Throughout the description and claims of this specification, the words “comprise” and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, or elements (or groups or sub-assemblies thereof) described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

Although certain embodiments have been described above in relation to electrical apparatus in the form of electronic ballasts for HID lamps, it will be appreciated that the invention is not limited to such forms of electrical apparatus, and the invention in its broadest is generally applicable to any other form of electrical apparatus in which a heat-generating component (which may also be described as a circuit element or device) is enclosed within a housing.

The reader's attention is directed to all papers and documents which are filed concurrently with or previous to this specification in connection with this application and which are open to public inspection with this specification, and the contents of all such papers and documents are incorporated herein by reference.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. We therefore claim as our invention all that comes within the scope and spirit of these claims.

I claim:

1. Electrical apparatus comprising:
a housing;
an electrical circuit located inside the housing and comprising a circuit component in which heat is generated during operation of the circuit;
a metallic component located inside the housing, for dissipating heat generated in the circuit component; and
a thermally conductive body arranged between a surface of the circuit component and a surface of the metallic component,
wherein the housing comprises a first housing portion and a second housing portion, the second housing portion being adapted to locate on the first housing portion in a closed position in which the electrical circuit, metallic component, and body are enclosed within the housing,
the second housing portion being adapted such that, when in said closed position, the second housing portion urges said surface of the circuit component towards said surface of the metallic component such that the body is in contact with both of said surfaces to assist transfer of heat generated in the circuit component to the metallic component.

2. Apparatus in accordance with claim 1, wherein the thermally conductive body is electrically insulating.

3. Apparatus in accordance with claim 2, wherein the thermally conductive body is a thermal pad.

4. Apparatus in accordance with claim 1, wherein the circuit component is one of:
an inductor; a winding; a transformer; a capacitor; a switching device; and a processor.

5. Apparatus in accordance with claim 1, wherein the apparatus is a ballast for a high intensity discharge (HID) lamp.

6. Apparatus in accordance with claim 1, wherein the first housing portion comprises a first plastic body, and the second housing portion comprises a second plastic body.

7. Apparatus in accordance with claim 1, wherein the second housing portion is adapted to urge, via the circuit component, a second surface of the metallic component against a surface of the first housing portion when in said closed position.

8. Apparatus in accordance with claim 7, wherein said surface of the first housing portion is an inner surface of a side wall of the first housing portion.

9. Apparatus in accordance with claim 1, wherein the second housing portion comprises an urging member arranged to extend into a volume enclosed by the housing when the second housing portion is in the closed position, the urging member being adapted to urge said surface of the circuit component towards said surface of the metallic component.

10. Apparatus in accordance with claim 9, wherein the urging member is rigid.

11. Apparatus in accordance with claim 10, wherein the second housing potion comprises a plastic body, and the urging member is an integral part of the plastic body.

12. Apparatus in accordance with claim 10, wherein the urging member comprises an urging surface shaped so as to progressively urge said surface of the circuit component towards said surface of the metallic component as the second housing portion is moved into the closed position.

13. Apparatus in accordance with claim 10, wherein the circuit component is mounted on a first side of a board, and the urging member is arranged to press on a second, opposite side of the board to urge said surface of the circuit component towards said surface of the metallic component when the second housing portion is in the closed position.

14. Apparatus in accordance with claim 13, wherein the urging member comprises an urging surface shaped so as to engage the second surface of the board and progressively urge said surface of the circuit component towards said surface of the metallic component as the second housing portion is moved into the closed position.

15. Apparatus in accordance with claim 14, wherein the urging surface comprises a curved ramp portion and a linear ramp portion.

16. Apparatus in accordance with claim 13, wherein said board is coupled to a main circuit board of the electric circuit.

17. Apparatus in accordance with claim 1, wherein the metallic component is attached to the first housing portion.

18. Apparatus in accordance with claim 17, wherein the metallic component is attached to the first housing portion at a single attachment point so as to permit relative movement between surfaces of the metallic element and first housing potion in response to differential thermal expansions and contractions.

19. Apparatus in accordance with claim 1, wherein the metallic component comprises at least part of a metallic inner housing.

20. Apparatus in accordance with claim 1, wherein the circuit component is a first circuit component, the thermally conductive body is a first thermally conductive body, and the metallic component is a first metallic component, the electrical circuit comprises a second circuit component in which heat is generated during operation of the circuit, the apparatus comprises a second metallic component located inside the housing, for dissipating heat generated in the second circuit component, and a second thermally conductive body arranged between a surface of the second circuit component and a surface of the second metallic component, the second housing portion being further adapted such that, when in said closed position, the second housing portion urges said surface of the first circuit component towards said surface of the first metallic component such that the first thermally conductive body is in contact with both of said surfaces to assist transfer of heat generated in the first circuit component to the first metallic component, and urges said surface of the second circuit component towards said surface of the second metallic component such that the second thermally conductive body is in contact with both of said surfaces to assist transfer of heat generated in the second circuit component to the second metallic component.

21. Apparatus in accordance with claim 20, wherein the first and second metallic components are first and second portions respectively of a metallic inner housing.

22. Apparatus in accordance with claim 21, wherein each of the first and second portions of the metallic inner housing is attached to the first housing portion.

23. Apparatus in accordance with claim 22, wherein the first and second potions of the metallic inner housing are attached to the first housing portion such that a thermal expansion gap is arranged between the first and second metallic inner housing portions.

24. Apparatus in accordance with claim 20, wherein the second housing portion is adapted to urge, via the first and second circuit components, respective surfaces of the first and second metallic components against respective inner surfaces of opposite walls of the first housing portion.

25. Apparatus in accordance with claim 24, wherein the second housing portion is adapted to support said opposite walls when in the closed position.

26. Apparatus in accordance with claim 24, comprising an urging member arranged to urge the first circuit component surface into thermal contact with the first thermally conductive body and urge the second circuit component surface into thermal contact with the second thermally conductive body at the same time.

27. Apparatus in accordance with claim 20, comprising a first urging member arranged to urge at least the first circuit component into contact with the first thermally conductive body, and a second urging member arranged to urge at least the second circuit component into contact with the second thermally conductive member.

28. Apparatus in accordance with claim 21, wherein the second housing portion further comprises a third portion of the metallic inner housing.

29. Apparatus in accordance with claim 1, further comprising a snap-fit mechanism adapted to secure the second housing portion in the closed position.

30. Electrical apparatus comprising:
a housing;
an electrical circuit located inside the housing and comprising a circuit component in which heat is generated during operation of the circuit; and
a metallic component located inside the housing, for dissipating heat generated in the circuit component,
wherein the housing comprises a first housing portion and a second housing portion, the second housing portion being adapted to locate on the first housing portion in a closed position in which the electrical circuit and metallic component are enclosed within the housing,
the second housing portion being adapted such that, when in said closed position, the second housing portion urges a surface of the circuit component against a surface of the metallic component to assist transfer of heat generated in the circuit component to the metallic component.

31. Electrical apparatus comprising:
a housing;
an electrical component located inside the housing and in which heat is generated during electrical operation of the electrical component; and
a metallic component located inside the housing, for dissipating heat generated in the electrical component,
wherein the housing comprises a first housing portion and a second housing portion, the second housing portion being adapted to locate on the first housing portion in a closed position in which the electrical component and metallic component are enclosed within the housing,
the second housing portion being adapted such that, when in said closed position, the second housing portion urges a surface of the electrical component against a surface of the metallic component to assist transfer of heat generated in the electrical component to the metallic component.

32. Electrical apparatus comprising:
a housing;
an electrical component located inside the housing and in which heat is generated during electrical operation of the electrical component;
a metallic component located inside the housing, for dissipating heat generated in the electrical component; and
a thermally conductive body arranged between a surface of the electrical component and a surface of the metallic component,
wherein the housing comprises a first housing portion and a second housing portion, the second housing portion being adapted to locate on the first housing portion in a closed position in which the electrical component, metallic component, and body are enclosed within the housing,
the second housing portion being adapted such that, when in said closed position, the second housing portion urges said surface of the electrical component towards said surface of the metallic component such that the body is in contact with both of said surfaces to assist transfer of heat generated in the electrical component to the metallic component.
